(19) United States
(12) Patent Application Publication
(10) Pub. No.: US 2024/0383103 A1
(43) Pub. Date: Nov. 21, 2024

(54) PROCESSING TOOL

(71) Applicant: DISCO CORPORATION, Tokyo (JP)

(72) Inventor: Yuki AKAHOSHI, Tokyo (JP)

(21) Appl. No.: 18/653,031

(22) Filed: May 2, 2024

(30) Foreign Application Priority Data
May 17, 2023 (JP) 2023-081472

(51) Int. Cl. B24D 3/00; B24D 5/14

(52) U.S. Cl. CPC B24D 3/00; B24D 5/14

(57) ABSTRACT

A processing tool for removing a chamfer of a wafer that is formed on its front surface with a central region and a peripheral surplus region, the chamfer being formed in the peripheral surplus region. The processing tool includes an annular grinding grindstone with an opening into which a spindle is inserted and having first and second side surfaces and a polishing grindstone formed on at least one of the first side surface or the second side surface. The processing tool is formed in such a manner as to satisfy both the following conditions (1) and (2):

$$H + h > L \qquad ( 1 )$$

$$L / 3 > h > L / 100 \qquad ( 2 )$$

where L is a length in a radial direction from a peripheral end of the chamfer to be removed, H is a width of the grinding grindstone, and h is a width of the polishing grindstone.

### BACKGROUND OF THE INVENTION

### Field of the Invention

The present invention relates to a processing tool for removing a chamfer of a wafer that is formed on its front surface with a central region and a peripheral surplus region surrounding the central region, the chamfer being formed in the periphery of the peripheral surplus region.

### Description of the Related Art

A wafer formed on its front surface with a plurality of devices such as integrated circuits (ICs) and large-scale integration (LSI) circuits in the state of being partitioned by a plurality of intersecting projected dicing lines (streets) has its back surface ground by a grinding apparatus to thereby be thinned to a predetermined thickness, after which the wafer is divided into individual device chips, and the thus divided device chips are used for electric apparatuses such as mobile phones and personal computers.

The grinding apparatus includes a chuck table that holds the wafer, a grinding unit having, in a rotatable manner, a grinding wheel in which grinding grindstones for grinding the wafer held by the chuck table are disposed in an annular pattern, a feeding mechanism that subjects the grinding unit to grinding feed, and a thickness measuring device for measuring the thickness of the wafer, and the grinding apparatus is able to grind the back surface of the wafer to thereby process the wafer to a desired thickness.

However, since a chamfer is formed at the periphery of the wafer, when the back surface of the wafer is ground to thin the wafer, the chamfer at the peripheral end of the wafer becomes a sharp knife edge, to cause a problem that cracks are generated from the periphery and extend into the device region, thereby damaging the devices and possibly injuring an operator.

In view of this problem, a technology of removing the chamfer formed at the peripheral end of a peripheral surplus region before the back surface of the wafer is ground has been proposed by the present applicant (see, for example, Japanese Patent Laid-open No. 2010-225976).

In addition, since cutting of the above-mentioned chamfer by a cutting grindstone causes chipping at the periphery of the wafer to result in lowering of quality, there has also been proposed, by the present applicant, a technology of removing the chipping by a grindstone having a fine texture, after roughly removing the chamfer by a grindstone having a coarse texture, to thereby enhance the quality of the wafer before grinding the back surface of the wafer (see Japanese Patent Laid-open No. 2014-003198).

### SUMMARY OF THE INVENTION

However, the processing that includes a removing step of roughly removing the chamfer by a grindstone surface having a coarse texture and a finishing step of, after the removing step, finishing the wafer by a grindstone surface having a fine texture has a problem that it takes time until the chamfer is removed, so that productivity is poor and the process is very troublesome.

Accordingly, it is an object of the present invention to provide a processing tool that is able to efficiently remove a chamfer of a wafer.

In accordance with an aspect of the present invention, there is provided a processing tool for removing a chamfer of a wafer that is formed on its front surface with a central region and a peripheral surplus region surrounding the central region, the chamfer being formed in a periphery of the peripheral surplus region. The processing tool includes an annular grinding grindstone having in its center an opening into which a spindle is inserted and having a first side surface and a second side surface, and a polishing grindstone formed on at least one of the first side surface or the second side surface. The processing tool is formed in such a manner as to satisfy both the following conditions (1) and (2):

$$H + h > L \qquad ( 1 )$$

$$L / 3 > h > L / 100 \qquad ( 2 )$$

where L is a length in a radial direction from a peripheral end of the chamfer to be removed, H is a width of the grinding grindstone, and h is a width of the polishing grindstone.

Preferably, a grain diameter of diamond abrasive grains constituting the polishing grindstone is selected according to a material of the wafer, and a grain diameter of diamond abrasive grains constituting the grinding grindstone is selected in a range of 1.5 to 5 times the grain diameter of the diamond abrasive grains constituting the polishing grindstone. Preferably, a bonding material constituting the polishing grindstone and the grinding grindstone is selected from a resin bond, a vitrified bond, and a metal bond. Preferably, the wafer is a semiconductor wafer that includes, in the central region, a device region in which a plurality of devices are partitioned by a plurality of intersecting streets.

According to the processing tool of the present invention, it is possible to roughly and efficiently remove a region having the length L in the radial direction from the peripheral end to be removed from the wafer and simultaneously finish a peripheral surface to be smooth, the peripheral surface constituting a removal region formed by removal of a part of the chamfer, so that productivity is enhanced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of the whole part of a cutting apparatus to which a processing tool of the present embodiment is mounted;

FIG. 2A is an enlarged perspective view of a part of a cutting unit of the cutting apparatus depicted in FIG. 1;

FIG. 2B is an exploded perspective view of the cutting unit depicted in FIG. 2A;

FIG. 3 is a perspective view depicting a mode of a wafer holding step of holding a wafer;

FIG. 4 is a perspective view depicting a mode of detecting a position to be processed of a chamfer;

FIG. 5 is a side view depicting the wafer of which the chamfer is detected in FIG. 4;

FIG. 6 is a perspective view depicting a mode in which a grinding unit is positioned above the wafer when a chamfer removing step is carried out;

FIG. 7 is a perspective view depicting a mode of removal of the chamfer in the chamfer removing step;

FIG. 8A is a partial enlarged side view depicting a mode in which a grindstone is caused to cut into the chamfer of the wafer; and

FIG. 8B is a partial enlarged side view depicting a mode in which a part of the chamfer is removed by the chamfer removing step.

### DETAILED DESCRIPTION OF THE PREFERRED EMBODIMENT

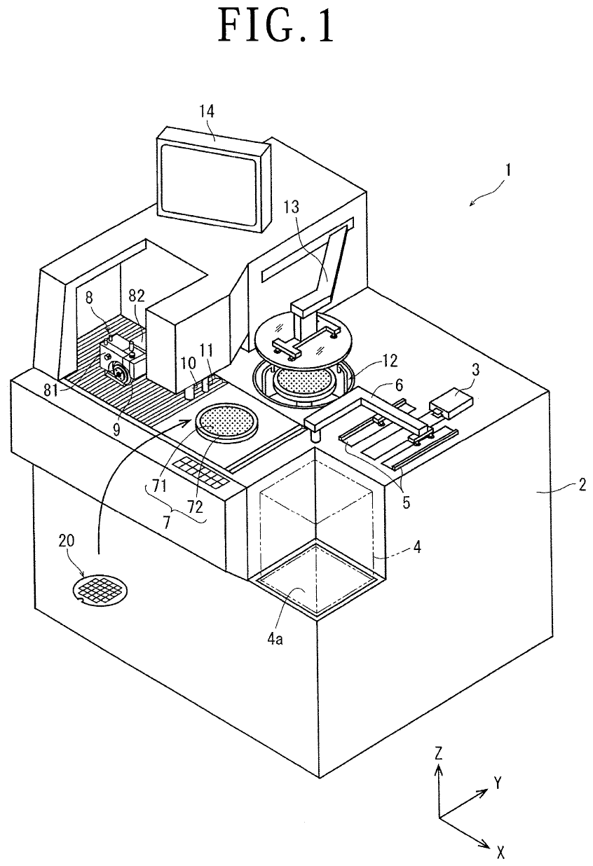

A processing tool according to an embodiment of the present invention will be described in detail below with reference to the attached drawings. FIG. 1 illustrates a cutting apparatus 1 including a cutting unit 8 to which a grindstone 9 as the processing tool of the present embodiment is mounted. The cutting apparatus 1 includes a substantially rectangular parallelepiped housing 2, a cassette 4 (depicted in a long and two short dashes line) mounted on a cassette table 4a of the housing 2, a conveying-in/out mechanism 3 that conveys out a wafer 20 from the cassette 4 onto a temporary placement table 5, a conveying mechanism 6 having a slewing arm for conveying the wafer 20 conveyed out onto the temporary placement table 5 onto a chuck table 7, the cutting unit 8 to which the grindstone 9 of the present embodiment for processing the wafer 20 held by the chuck table 7 is mounted and which includes a grindstone cover 81 and a spindle housing 82, an alignment unit 10 for imaging a processing region of the wafer 20 held by the above-mentioned chuck table 7 and for detecting a region to be processed by the cutting unit 8, a height detector 11 which is disposed adjacent to the alignment unit 10 in a Y-axis direction and which is for detecting the thickness of the wafer 20 held by the chuck table 7, a conveying-out mechanism for cleaning 13 that conveys the wafer 20 from a conveying-in/out position where the chuck table 7 is located in FIG. 1 to a cleaning device 12, and a display unit 14 disposed at an upper part of the housing 2.

The chuck table 7 is configured by a suction chuck 71 that is formed from a gas-permeable porous member and that constitutes a holding surface and a frame body 72 surrounding the suction chuck 71, and is connected to unillustrated suction means through the frame body 72. By operating the suction means, it is possible to generate a negative pressure at an upper surface of the suction chuck 71 and hold a workpiece under suction.

Inside the housing 2, there are provided an X-axis feeding mechanism for processing feeding of the chuck table 7 in an X-axis direction, a Y-axis feeding mechanism for indexing feeding of the cutting unit 8 in the Y-axis direction orthogonal to the X-axis direction, a Z-axis feeding mechanism for cutting-in feeding by moving in a Z-axis direction (vertical direction) orthogonal to the X-axis direction and the Y-axis direction, and a rotational drive mechanism for rotating the chuck table 7, and there is disposed an unillustrated controller for controlling each of operating sections of the cutting apparatus 1.

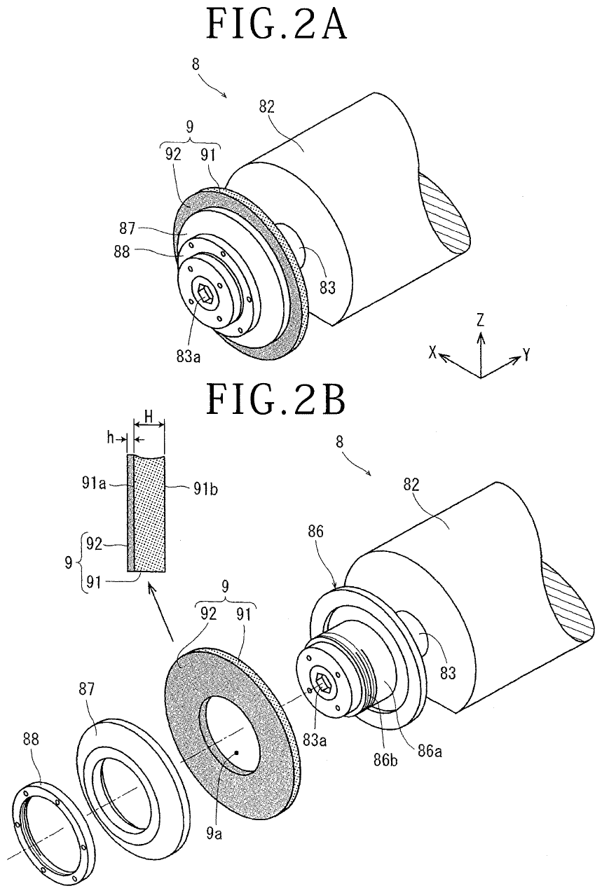

FIG. 2A is a perspective view depicting, in an enlarged form, a major part of the cutting unit 8 disposed in the cutting apparatus 1 depicted in FIG. 1, and FIG. 2B depicts a perspective view, in an exploded state, of the configuration of FIG. 2A. Note that, in FIGS. 2A and 2B, the grindstone cover 81 covering the grindstone 9 mentioned above is omitted for convenience of description. The cutting unit 8 includes the spindle housing 82, a spindle 83 rotatably held by the spindle housing 82, and the grindstone 9 that is mounted to a tip part 83a of the spindle 83 and is selected in such a manner as to satisfy the conditions described in detail later. An unillustrated rotational drive source such as a motor is accommodated on the other end side of the spindle housing 82, and the rotational drive source rotates the spindle 83 to thereby rotate the grindstone 9 at high speed.

In describing the cutting unit 8 in further detail, as understood from FIG. 2B, the cutting unit 8 includes a fixed flange 86 formed on the side of the tip part 83a of the spindle 83, a boss section 86a projecting in an axial direction from the center of the fixed flange 86, a detachable flange 87 that engages with the boss section 86a to clamp the grindstone 9 in cooperation with the fixed flange 86, and a nut 88 that makes screw engagement with a male screw 86b formed at a side surface of the boss section 86a and that fastens the detachable flange 87. An opening 9a of the grindstone 9 is formed correspondingly to the diameter of the boss section 86a. By inserting the boss section 86a into the opening 9a of the grindstone 9 and mounting the detachable flange 87 to the boss section 86a to thereby put the nut 88 into screw engagement with the male screw 86b and fasten them, the grindstone 9 is clamped between and firmly fixed by the fixed flange 86 and the detachable flange 87.

As depicted in FIG. 2B, the grindstone 9 includes an annular grinding grindstone 91 and an annular polishing grindstone 92 formed as one body with the grinding grindstone 91. As a part being depicted by an enlarged sectional view at the left upper side of FIG. 2B, the grinding grindstone 91 is a flat plate-shaped grindstone having a first side surface 91a and a second side surface 91b, whereas the polishing grindstone 92 is formed on at least one of the first side surface 91a or the second side surface 91b, and, in the present embodiment, the polishing grindstone 92 is formed on the first side surface 91a side. Note that the configuration of the grindstone 9 constituting the processing tool of the present invention is not limited to the configuration in which the polishing grindstone 92 is formed only on one side surface of the grinding grindstone 91 as described above, and the polishing grindstone 92 may be formed on both the first side surface 91a and the second side surface 91b. Abrasive grains constituting the polishing grindstone 92 and the grinding grindstone 91 are, for example, diamond abrasive grains, and the bonding material is preferably selected from, for example, a resin bond, a vitrified bond, and a metal bond. The polishing grindstone 92 is a grindstone having a fine texture for finishing a surface to be brought into contact with the workpiece to be smooth, and the average grain diameter (hereinafter referred to as a “grain diameter”) of the diamond abrasive grains constituting the polishing grindstone 92 is appropriately selected according to the material of the workpiece, and is set to be small as compared with the grain diameter of the diamond abrasive grains constituting the grinding grindstone 91. The width (thickness) of the grinding grindstone 91 and the width (thickness) of the polishing grindstone 92 in the present invention are required to satisfy predetermined conditions, of which the details will be described later.

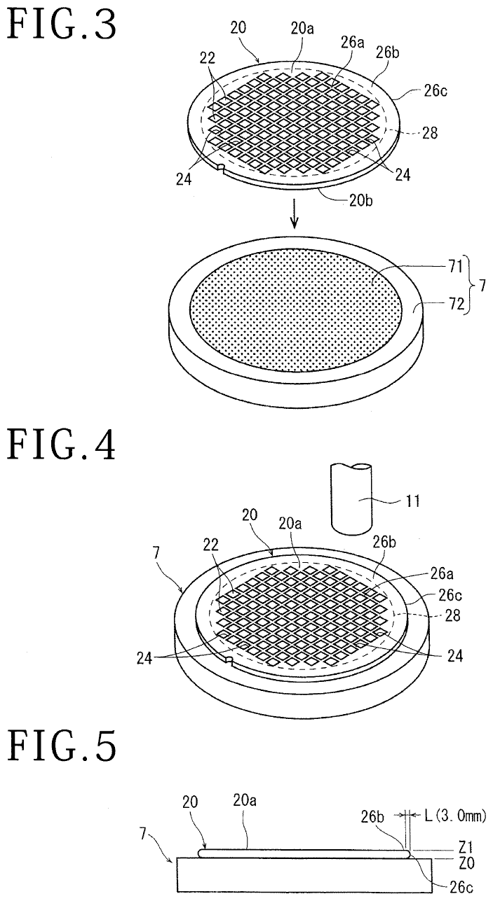

With reference to FIGS. 3 to 8B, the processing method for removal of a chamfer of a wafer by use of the grindstone 9 of the processing tool of the present embodiment and the conditions of the grinding grindstone 91 and the polishing grindstone 92 constituting the grindstone 9 will be described below.

At the time of carrying out the processing for removing, by the cutting apparatus 1 depicted in FIG. 1, a chamfer 26c of the wafer 20 depicted in FIG. 3, first, a grindstone preparing step is carried out. The wafer 20 to be processed in the present embodiment is a wafer of a semiconductor (for example, silicon) which is formed on its front surface 20a with a plurality of devices 22 in the state of being partitioned by a plurality of intersecting streets 24, and includes a central region 26a where the devices 22 are formed, a peripheral surplus region 26b surrounding the central region 26a, and the chamfer 26c where chamfering has been conducted at a peripheral end of the peripheral surplus region 26b. In FIG. 3, an annular demarcation line 28 (depicted in a broken line) for dividing the central region 26a and the peripheral surplus region 26b from each other is described, but this is added for convenience of description, and, in practice, the demarcation line 28 is not formed on the front surface 20a of the wafer 20. Here, the wafer 20 has a thickness of, for example, 700 μm, and a length L (see FIG. 5) in the radial direction from the peripheral end of the chamfer 26c to be removed is preset to 3.0 mm. The grindstone 9 formed in such a manner as tso satisfy both the following conditions (1) and (2) is adopted:

$$H + h > L \qquad ( 1 )$$

$$L / 3 > h > L / 100 \qquad ( 2 )$$

where H is the width of the grinding grindstone 91, h is the width of the polishing grindstone 92, and L (=3.0 mm) is the length in the radial direction from the peripheral end to be removed. In the present embodiment, while the length L in the radial direction from the peripheral end of the chamfer 26c to be removed is 3.0 mm, the grindstone 9 having a diameter of 58 mm in which the width H of the grinding grindstone 91 is 3.0 mm, the width h of the polishing grindstone 92 is 0.3 mm, and the total width is 3.3 mm is prepared.

The condition (2) of the grindstone 9 prepared by the above-mentioned grindstone preparing step is further preferably that the width h of the polishing grindstone 92 is set in the range of smaller than L/20 and larger than L/60. In addition, the grain diameter of the diamond abrasive grains constituting the polishing grindstone 92 is selected according to the physical properties of silicon constituting the wafer 20, and the grain diameter of the diamond abrasive grains constituting the grinding grindstone 91 is preferably selected in the range of 1.5 to 5 times the grain diameter of the diamond abrasive grains constituting the polishing grindstone 92. More specifically, in a case where the grain diameter of the diamond abrasive grains constituting the polishing grindstone 92 is selected to be 3 to 10 μm, the grain diameter of the diamond abrasive grains constituting the grinding grindstone 91 is set in the range of 15 to 50 μm, that is, 1.5 to 5 times the grain diameter of the diamond abrasive grains constituting the polishing grindstone 92. When the grindstone 9 satisfying the above-described conditions has been prepared in the grindstone preparing step, the grindstone 9 is mounted to the cutting unit 8 as has been described with reference to FIG. 2B. In the present embodiment, the grindstone 9 is mounted in such a manner that the grinding grindstone 91 is disposed on the side of the tip part 83a of the spindle 83, whereas the polishing grindstone 92 is disposed on the side of the spindle housing 82.

When the grindstone preparing step has been carried out, the wafer 20 is conveyed out from the cassette 4 of the cutting apparatus 1 described with reference to FIG. 1, temporarily placed on the temporary placement table 5 by the conveying-in/out mechanism 3, sucked from the temporary placement table 5 by operation of the conveying mechanism 6, and conveyed onto the chuck table 7. In this instance, as depicted in FIG. 3, the wafer 20 is mounted on the chuck table 7, with its back surface 20b directed downward, and unillustrated suction means is operated to generate a negative pressure at the suction chuck 71 and hold the wafer 20 thereon under suction.

When a wafer holding step has been carried out as described above, the above-mentioned X-axis feeding mechanism is operated to position the wafer 20 together with the chuck table 7 directly under the alignment unit 10, the wafer 20 is imaged, and the center of the wafer 20 and a position, in the peripheral surplus region 26b, of a region having the length L (3.0 mm) in the radial direction from the peripheral end of the chamfer 26c to be removed are detected. Further, as depicted in FIG. 4, the thickness of the region of the chamfer 26c to be removed, more specifically, a height Z0 of the front surface of the chuck table 7 and a height Z1 of the front surface 20a of the chamfer 26c of the wafer 20 are detected, as depicted in FIG. 5, the difference (Z0−Z1) thereof is calculated as the thickness of the wafer 20, and information regarding the processing region thus detected is stored in the unillustrated controller.

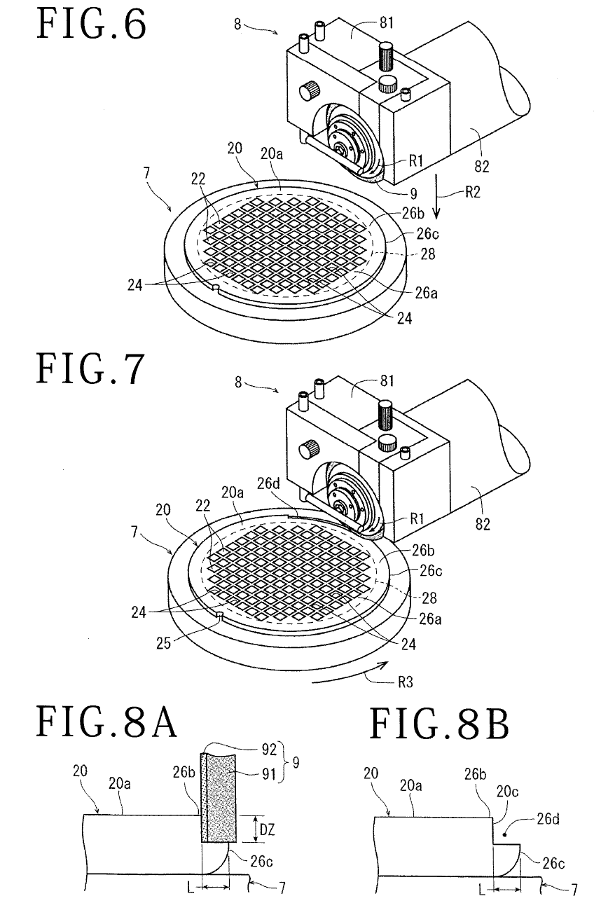

Next, based on the information regarding the processing region of the chamfer 26c to be removed, the information being detected by the above-mentioned processing position detecting step and stored in the controller, the X-axis feeding mechanism and the Y-axis feeding mechanism of the cutting apparatus 1 described above are operated, whereby the chamfer 26c of the wafer 20 is positioned directly under the grindstone 9 mounted to the cutting unit 8, as depicted in FIG. 6. In this instance, the position of the polishing grindstone 92 of the grindstone 90 is positioned on the upper side of a position conforming to the length L in the radial direction from the peripheral end to be removed. Then, the grindstone 9 is rotated at a predetermined rotational speed (for example, 30,000 rpm) in a direction indicated by an arrow R1, and the above-mentioned Z-axis feeding mechanism is operated to lower the cutting unit 8 in a direction indicated by an arrow R2, thereby causing the grindstone 9 to cut into the chamfer 26c of the wafer 20. Together with this, the chuck table 7 is rotated at least one revolution at a predetermined rotational speed (for example, 0.8 to 3 rpm) in a direction indicated by an arrow R3, as depicted in FIG. 7.

In this instance, the grindstone 9 is put into cutting-in feed to remove the region having the length L in the radial direction from the peripheral end and reach the position of a predetermined cutting-in depth DZ (in the present embodiment, 30 μm), as depicted in FIG. 8A. By the above operations, the chamfer 26c forming the peripheral end of the peripheral surplus region 26b of the wafer 20 is removed in an annular shape with the width of the length L in the radial direction from the peripheral end and by an amount of the predetermined cutting-in depth DZ, whereby a chamfer removing step is completed, as depicted in FIG. 8B. Note that the above-mentioned cutting-in depth DZ is set according to the thickness of the wafer 20 finished by grinding from the back surface 20b side of the wafer 20 by a back surface grinding step (details are omitted) to be carried out after the processing method of the present embodiment is conducted, and, in the present embodiment, since the wafer 20 is finished to a thickness of 250 μm by grinding the back surface 20b in the back surface grinding step carried out later, it is sufficient that the cutting-in depth DZ in the chamfer removing step is 300 μm.

In the present embodiment, the size of the width H of the grinding grindstone 91 plus the width h of the polishing grindstone 92 is formed to be larger than the length L in the radial direction from the peripheral end of the chamfer 26c to be removed, the chamfer 26c forming the peripheral end part of the peripheral surplus region 26b (condition (1)), and the width h of the polishing grindstone 92 is formed to be smaller than L/3 and greater than L/100 (condition (2)). As a result, as has been described above, by positioning the polishing grindstone 92 on the center side of the wafer 20, positioning the grinding grindstone 91 on the outside, cutting into the chamfer 26c of the wafer 20 at the predetermined cutting-in depth DZ while rotating the grindstone 9, and rotating the wafer 20 held by the chuck table 7, at least one revolution, it is possible to roughly remove the region having the length L in the radial direction from the peripheral end of the chamfer 26c to be removed and simultaneously finish the peripheral surface 20c constituting a removal region 26d formed by removal of a part of the chamfer 26c, as depicted in FIG. 8B, so that productivity is enhanced.

As for the above-described condition (2), the width h of the polishing grindstone 92 is more preferably set to be smaller than L/20 and greater than L/60; for example, in a case where the length L in the radial direction from the peripheral end to be removed is 3.00 mm (3,000 μm), it is preferable to set the width h of the polishing grindstone 92 to 50 to 150 μm and adjust the width H of the grinding grindstone 91 in the range of 2,950 to 3,050 μm, thereby setting the total width (H+h) of the grindstone 9 to 3,100 μm. With the width H of the grinding grindstone 91 and the width h of the polishing grindstone 92 set in such ranges, it is possible to roughly remove, by the grinding grindstone 91, the region having the length L in the radial direction from the peripheral end to be removed from the wafer 20 and simultaneously finish the peripheral surface 20c constituting the removal region 26d formed by removal of a part of the chamfer 26c, so that productivity is enhanced.

In addition, the grain diameter of the diamond abrasive grains constituting the grinding grindstone 91 is preferably formed in the range of 1.5 to 5 times the grain diameter of the diamond abrasive grains constituting the polishing grindstone 92; more specifically, in the case where the grain diameter of the diamond abrasive grains constituting the polishing grindstone 92 is 3 to 10 μm in consideration of the material of the wafer 20, it is recommendable that the grain diameter of the diamond abrasive grains constituting the grinding grindstone 91 is set in the range of 15 to 50 μm. With this setting, the intimacy at the time of forming the grinding grindstone 91 and the polishing grindstone 92 as one body is secured, the grindstone 9 is formed firmly, durability thereof is enhanced, and it is possible to roughly and efficiently remove the region having the length L in the radial direction from the peripheral end to be removed from the wafer 20 and simultaneously finish the peripheral surface 20c to be smooth, the peripheral surface 20c constituting the removal region 26d formed by removal of a part of the chamfer 26c.

In the above-described embodiment, the polishing grindstone 92 is mounted to the side of the tip part 83a of the spindle housing 82, and the grinding grindstone 91 is mounted to the side of the spindle housing 82. However, the present invention is not limited to this configuration, and the chamfer removing step of the processing method described above can be carried out also by mounting the polishing grindstone 92 to the side of the spindle housing 82 and mounting the grinding grindstone 91 to the side of the tip part 83a of the spindle 83. In this case, it is recommendable to carry out the chamfer removing step by positioning the grindstone 9 of the cutting unit 8 such that the polishing grindstone 92 side is on the center side of the wafer 20 in the radial direction, more specifically, for example, positioning the grindstone 9 on the left lower side while straddling the wafer 20 depicted in FIG. 7 (the region where a notch 25 of the wafer 20 is positioned as depicted in FIG. 7), and rotating the chuck table 7.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing tool for removing a chamfer of a wafer that is formed on its front surface with a central region and a peripheral surplus region surrounding the central region, the chamfer being formed in a periphery of the peripheral surplus region, the processing tool comprising:
an annular grinding grindstone having in its center an opening into which a spindle is inserted and having a first side surface and a second side surface; and
a polishing grindstone formed on at least one of the first side surface or the second side surface,
wherein the processing tool is formed in such a manner as to satisfy both the following conditions (1) and (2):
$$H + h > L \qquad ( 1 )$$
$$L / 3 > h > L / 100 \qquad ( 2 )$$
where L is a length in a radial direction from a peripheral end of the chamfer to be removed, H is a width of the grinding grindstone, and h is a width of the polishing grindstone.

2. The processing tool according to claim 1, wherein a grain diameter of diamond abrasive grains constituting the polishing grindstone is selected according to a material of the wafer, and a grain diameter of diamond abrasive grains constituting the grinding grindstone is selected in a range of 1.5 to 5 times the grain diameter of the diamond abrasive grains constituting the polishing grindstone.

3. The processing tool according to claim 2, wherein a bonding material constituting the polishing grindstone and the grinding grindstone is selected from a group consisting of resin bond, a vitrified bond, and a metal bond.

4. The processing tool according to claim 1, wherein the wafer is a semiconductor wafer that includes, in a central region, a device region in which a plurality of devices are partitioned by a plurality of intersecting streets.
